(19) United States
(12) Patent Application Publication
(10) Pub. No.: US 2026/0123264 A1
(43) Pub. Date: Apr. 30, 2026

(54) MANUFACTURING DEVICE FOR DISPLAY DEVICE AND MANUFACTURING METHOD OF DISPLAY DEVICE USING THE SAME

(71) Applicant: Samsung Display Co., Ltd., Yongin-Si (KR)

(72) Inventors: DONGWOO KIM, Yongin-si (KR); GEUMCHEOL KIM, Yongin-si (KR); HEE SOO HAN, Yongin-si (KR)

(21) Appl. No.: 19/310,565

(22) Filed: Aug. 26, 2025

(30) Foreign Application Priority Data
Sep. 24, 2024 (KR) 10-2024-0128641

(51) Int. Cl. H10K 71/50; H10K 59/12

(52) U.S. Cl. CPC H10K 71/50; H10K 59/1201

(57) ABSTRACT

A manufacturing device for a display device including an object that has a display panel and a circuit board connected to the display panel, the manufacturing device including a first chuck that chucks a first portion of the circuit board and bends the object, and a second chuck that chucks a second portion of the display panel.

### CROSS-REFERENCE TO RELATED APPLICATION(S)

This application claims priority and benefit, under 35 U.S.C. § 119, to Korean Patent Application No. 10-2024-0128641 filed on September 24, 2024, the content of which in its entirety is herein incorporated by reference.

### BACKGROUND

### 1. Field

The disclosure relates to a manufacturing device for a display device including a bending device. More particularly, the disclosure relates to the manufacturing device for the display device including the bending device and a manufacturing method of the display device using the manufacturing device for the display device.

### 2. Description of the Related Art

As information technology advances, the importance of display devices that connect users to information is increasing rapidly. As a result, use of display devices such as liquid crystal display devices (“LCD”s), organic light emitting display devices (“OLED”s), and plasma display devices (“PDP”s) has been increasing.

A display device includes a display area where a plurality of pixels is located, and a peripheral area where a drive circuit chip for driving the plurality of pixels is located.

Connectors may be located in the peripheral area. Printed circuit board (“PCB”), which is one of moving parts in a display device, may be located in the connector. For example, a circuit board may include a flexible printed circuit board (“FPCB”), or the like.

### SUMMARY

Embodiments of the disclosure provide a manufacturing device for a display device with reduced dead space.

Embodiments of the disclosure provide a manufacturing method of a display device using the manufacturing device for the display device.

According to an embodiment, a manufacturing device for a display device that includes an object having a display panel and a circuit board connected to the display panel is presented. The manufacturing device includes a first chuck that chucks the circuit board and bends the object, and a second chuck that chucks the display panel.

In an embodiment, the manufacturing device may further include a controller that independently controls an operation of the first chuck and the second chuck.

In an embodiment, the controller may further include a first controller that receives a dimension of the object and determines movement paths for the first chuck and the second chuck based on the dimension.

In an embodiment, the controller may further include a second controller that determines whether an alignment error of the display panel and the circuit board satisfies a first reference range.

In an embodiment, the controller may further include a third controller that determines whether a bending error, including a shape error and a position error of a bending portion of the object, satisfies a second reference range.

In an embodiment, the second chuck may move in a direction of reducing the bending error in response to the bending error being outside of the second reference range.

In an embodiment, the bending portion may be located between a first flat portion in the display panel and the second flat portion in the circuit board. After the object is bent, the first flat portion and the second flat portion may be stacked on each other, and the bending portion may have a first radius. The second chuck moves in the direction of reducing the bending error, causing the bending portion may have a different radius from the first radius.

In an embodiment, the manufacturing device for the display device may further include a camera located to photograph a side surface of the bending portion.

In an embodiment, the controller may further include a fourth controller that compares the alignment error and the bending error.

In an embodiment, the second chuck may further include a vacuum suction pad for vacuum suctioning a portion of the display panel.

According to an embodiment, a manufacturing method of a display device of disclosure includes preparing an object including a circuit board connected to a display panel, chucking a portion of the circuit board, chucking a portion of the display panel; and bending the object to form a first flat portion, a second flat portion stacked on the first flat portion, and a bending portion having a first radius between the first flat portion and the second flat portion.

In an embodiment, the method may further include determining whether the bending error, including a shape error and a position error of the bending portion, satisfies a second reference range, after bending the object.

In an embodiment, the method may further include modifying a shape of the bending portion in response to the bending error being outside the second reference range.

In an embodiment, the bending portion may have a second radius that is different from the first radius, after modifying the shape of the bending portion.

In an embodiment, the method may further include determining whether the alignment error of the display panel and the circuit board satisfies a first reference range, before bending the object and determining whether the bending error satisfies the second reference range.

In an embodiment, the method may determine whether the bending error satisfies the second reference range in response to the alignment error satisfying the first reference range, wherein the bending error may be determined based on an image photographed of a side surface of the bending portion.

In an embodiment, the method may entail determining whether the shape and the position of the bending portion satisfy the second reference range before modifying the bending shape, and comparing the alignment error and the bending error.

In an embodiment, the bending shape may be modified in response to the alignment error being smaller than or equal to the bending error.

In an embodiment, the method may further include inputting a dimension of the object before chucking the object, and generating a first movement path for forming the bending portion and a second movement path for modifying the bending shape based on the dimension.

In an embodiment, the method entails vacuum suctioning the portion of the display panel in the chucking the portion of the display panel, the portion of the display.

According to an embodiment, the manufacturing device for the display device may include the object including the display panel and the circuit board connected to the display panel, the first chuck which chucks the first portion of the circuit board and bends the object, and the second chuck which chucks the second portion of the display panel. The bending shape is achieved using the first chuck, and the bending shape is precisely controlled using the second chuck, thereby bezel-less display device with reduced a dead space may be manufactured by using the manufacturing device for the display device and the manufacturing method of the display device using the manufacturing device for the display device.

In addition, the manufacturing device for the display device may further include a controller that independently controls operations of the first chuck and the second chuck. The controller may include a first controller that is inputted the dimension of the object and generates movement paths of the first chuck and the second chuck based on the dimension. Accordingly, various bending trajectories may be implemented using one device, and display devices with various dimension may be manufactured.

In addition, the controller included in the manufacturing device for the display device may determine whether the alignment error of the display panel and the circuit board satisfies the first reference range, determine the bending error including the shape error and the position error of the bending portion where the object is bent satisfies the second reference range, and may be moved the second chuck in the direction to reduce the bending error within a range where the alignment error is smaller than the bending error. Accordingly, the manufacturing device for the display device and the manufacturing method of the display device may minimize the dead space and simultaneously compensate for the alignment error.

In addition, the manufacturing device for the display device may further include the camera located to photograph the side surface of the bending portion. Accordingly, the manufacturing device for the display device and the manufacturing method of the display device may check the bending shape in real time and control the bending shape more precisely.

### BRIEF DESCRIPTION OF THE DRAWINGS

The above and other features of embodiments of the disclosure will become more apparent with reference to the description below and accompanying drawings.

FIGS. 1 and 2 illustrate a manufacturing device for a display device according to an embodiment of the disclosure.

FIG. 3 is a block view of a controller included in the manufacturing device for the display device of FIG. 1.

FIGS. 4, 5, and 6 are illustrate images taken by the camera included in the manufacturing device for the display device of FIGS. 1 and 2.

FIG. 7 is a flow chart illustrating the manufacturing method of the display device according to an embodiment of the disclosure.

FIGS. 8, 9, 10, 11, 12, 13, 14, and 15 are views illustrating the manufacturing method of the display device of FIG. 7.

FIG. 16 is a top view of the display panel of the display device manufactured using the manufacturing device for the display device of FIG. 1 and manufacturing method of the display device of FIG. 7.

FIG. 17 is a cross-sectional view along X-X′ line of FIG. 16.

### DETAILED DESCRIPTION OF THE EMBODIMENTS

The disclosure may be subjected to various modifications and transformations, and it is intended to describe certain embodiments of the disclosure in detail with reference to drawings. The effects and characteristics of the disclosure and the method of achieving them will be clarified by referring to the embodiments described in detail with the accompanying drawings. However, it should be understood that the disclosure is not limited to the embodiments disclosed below, and may cover various forms or modifications that is within the scope of the skilled person in the art.

When describing embodiments of the disclosure with reference to the drawings, the same or similar elements may be identified using the same reference numerals, and redundant descriptions thereof may be omitted.

In the following description, the terms, such as “first,” “second,” or the like., may be used only to distinguish one element from another and do not intend to be used in a definite sense.

In the following description, singular expressions may include plural expressions, unless the context clearly indicates otherwise.

In the following description, terms such as “include,” “have,” “comprise” and their variations, may indicate the presence of the features or elements described in the specification but do not preclude the possibility of additional features or elements being presented.

In the following description, when a part of a layer, area, or element is referred to as being “on” another part of the layer, area or element, it may indicate not only that the part of the layer, area or element is directly on another part of the layer, area, or element, but also that the part of the layer, area or element is disposed indirectly on another part of the layer, area or element, i.e., a third layer, area or element may be interposed between the two layers, areas, or elements.

In the drawings, elements may be exaggerated or reduced in size for ease of explanation. For example, the size and thickness of each element or configuration shown in the drawing are arbitrarily illustrated for ease of description, and the disclosure is not necessarily limited to what is shown.

In the following descriptions, the first, second, and third directions may indicate directions along x-axis, and the y-axis and z-axis but the disclosure is not limited to the three axes on the Cartesian coordinate system. For example, the x, y, and z axes may be orthogonal to each other, but they can also indicate different directions that are not orthogonal to each other.

If an embodiment can be implemented differently, a particular process sequence may be performed in an order different from what is described. For example, two processes described consecutively may be performed substantially simultaneously, or in the opposite order of the described sequence.

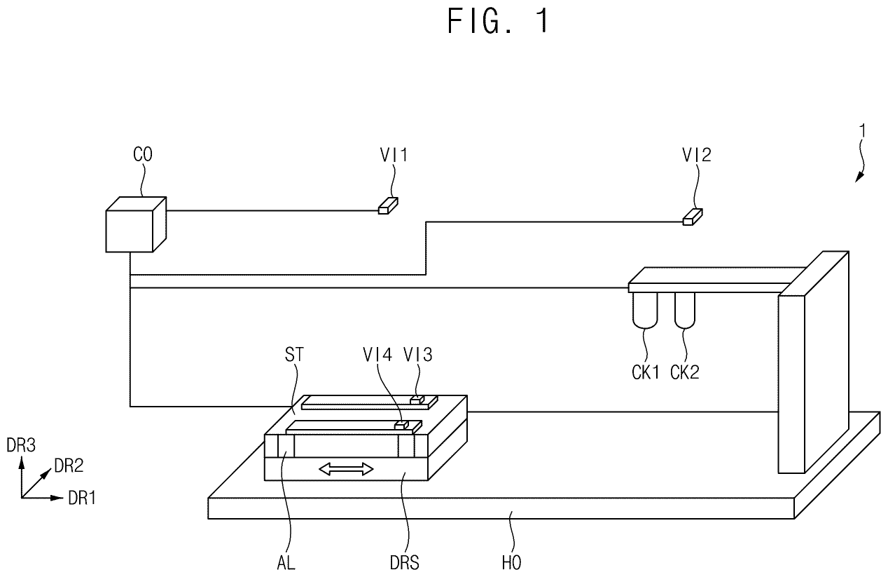

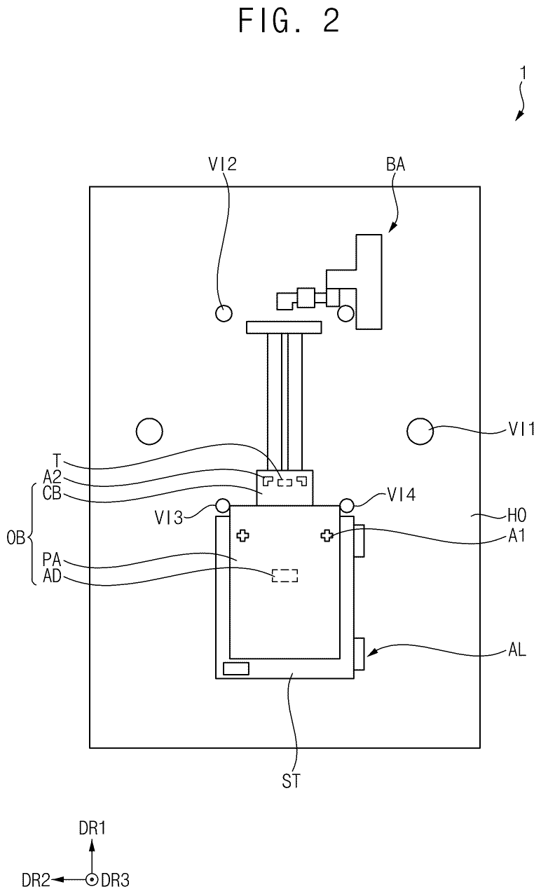

FIGS. 1 and 2 illustrate a manufacturing device for a display device according to an embodiment of the disclosure.

Referring to FIGS. 1 and 2, a manufacturing device for a display device according to an embodiment of the disclosure 1 may include a housing HO, a stage ST, a first chuck CK1, a driver DRS, an aligner AL, a first sensor VI1, a second sensor VI2, a third sensor VI3, a fourth sensor VI4, and a controller CO.

The manufacturing device for the display device according to an embodiment of the disclosure 1 may include a bending device that bends a portion of an object OB to be processed.

The housing HO may include multiple frames, plates, or the like. For example, the housing HO may have a chamber form. However, the disclosure is not limited thereto.

The object OB may include an electronic component and an adhesive AD. The electronic component may include a display panel PA and a circuit board CB that is connected to the display panel PA.

Some or all of the objects OB may have flexible properties. For example, a substrate of the display panel PA may include plastic, and the circuit board CB may also include the plastic. In this case, the display panel PA and circuit board CB may be bent in whole or in part.

For example, the display panel PA and the circuit board CB may include a display panel PA including a glass substrate, a driver integrated chip (“IC”), and a circuit board CB (chip on glass (“COG”) method).

For example, a film on which a thin-film printed circuit with the display panel PA and the driver IC may be located on the glass substrate, and the circuit board CB may be located on the film (chip on film (“COF”) method).

For example, the display panel PA, the driver IC, and the circuit board CB may be located on the polyimide substrate (chip on plastic (“COP”) method).

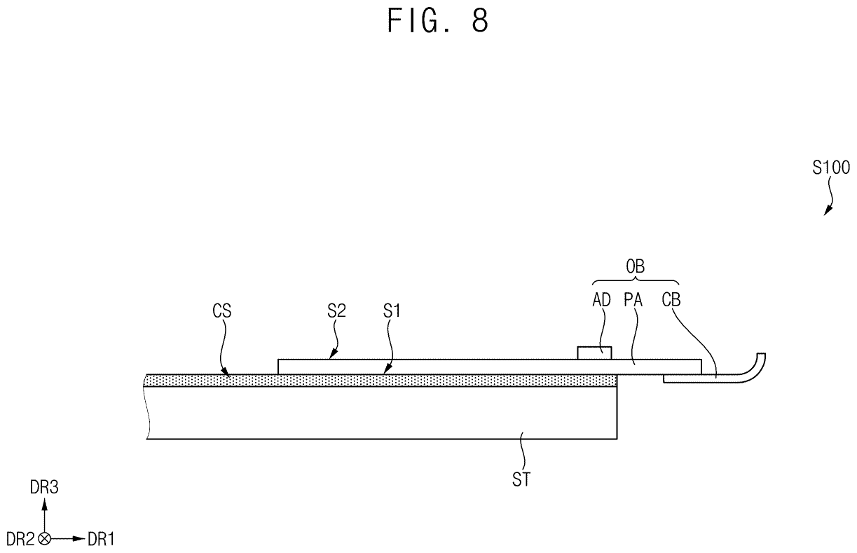

For example, the electronic component may include a first surface S1 and a second surface S2 (see FIG. 8). For example, the first surface S1 may be opposite to the second surface S2 (for example, in a third direction DR3). For example, the first surface S1 may be adjacent to the stage ST, and the second surface S2 may be farther from the stage ST than the first surface S1 (refer to FIG. 8).

A display area may be defined either in the second surface or in the first surface of the display panel PA. For example, the display area may be defined in the second surface, and the first surface may be a back surface on which the display area is not formed.

For example, the object OB may be disposed on the stage ST. For example, the stage ST may include a chuck CS. The chuck CS may be a device that fixes the electronic component to the stage ST. For example, the chuck CS may include an electrostatic chuck, an adhesive chuck, a clamp, a jig, a flow path connected to a pump, or the like.

For example, the first chuck CK1 may be located on the housing HO as depicted in FIG. 1.

In an embodiment, the first chuck CK1 may chuck a portion of the object OB and bend a portion of the object OB. For example, the first chuck CK1 may include a first support, a first linear driver, and a first rotator.

For example, the first support may extend in the third direction DR3. For example, the third direction DR3 may be a direction that crosses a surface of the housing HO.

For example, the surface of the housing HO may be defined by a first direction DR1 and a second direction DR2. The first direction DR1, the second direction DR2, and the third direction DR3 may cross one another. For example, the first direction DR1, the second direction DR2, and the third direction DR3 may be perpendicular to each other. The third direction DR3 may be an opposite direction to the direction of gravity.

For example, the first linear driver may be connected to the first support and may make a linear motion in one direction (for example, in the first direction DR1, in the second direction DR2, and/or in the third direction DR3). For example, the first linear driver may include a ball screw and a motor connected with the ball screw. However, the disclosure is not limited thereto. For example, the first linear driver may include a pulley and a belt, a linear motor, or the like.

For example, the first rotator may include a first chucking device and a first rotary device.

For example, the first chucking device may include an electrostatic chuck, an adhesive chuck, a clamp, a jig, a flow path connected with a pump, or the like. For example, the first chucking device may chuck the object OB by avoiding terminals, pads, conductors, or the like, formed on the object OB. For example, the first chucking device may chuck a chucking part T.

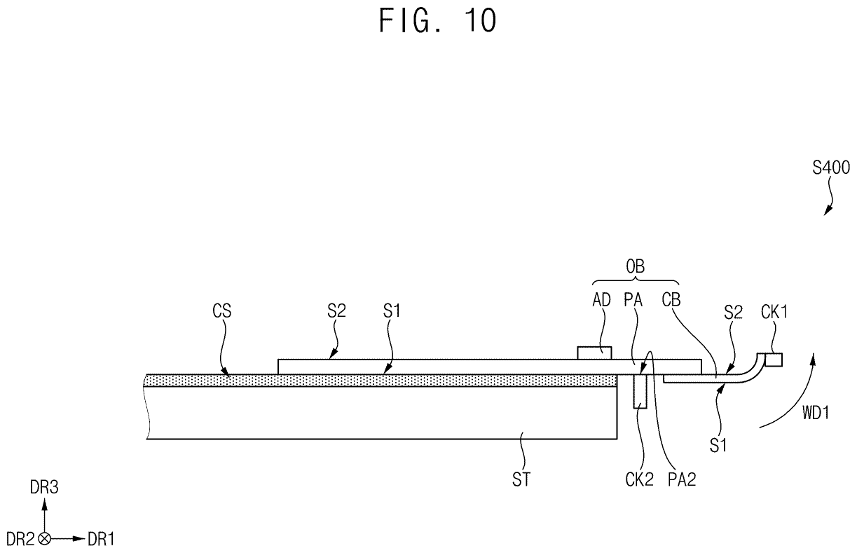

For example, the first rotator may include a rotary motor and a gear unit connected with the rotary motor, a rotary cylinder, a rotary pulley connected with the rotary motor, a rotary belt connected with the rotary pulley, or the like. However, the disclosure is not limited thereto. For example, the first rotator may move along a selectable bending path (for example, a first movement path WD1 of FIG. 10).

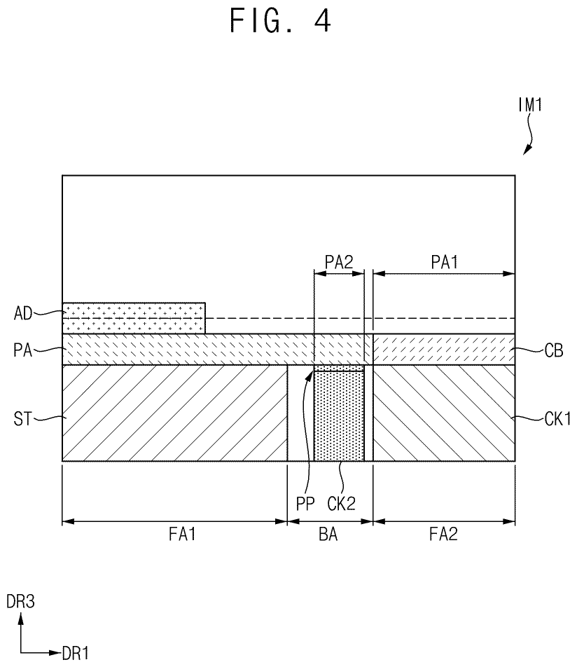

According to an embodiment, a portion of the display panel PA (i.e., the first bending portion) may be bent (refer to a bending portion BA, BA′ of FIGS. 4, 5, and 6). For example, the first bending portion of the display panel PA might not include the terminal, the pad, the line, or the like. In addition, a pixel might not be located in the first bending portion. However, the disclosure is not limited to any particular location of the pixel. For example, a portion of the circuit board CB (i.e., a second bending portion) may be bent (not shown). The terminal, the pad, the line, or the like might not be formed in the second bending portion.

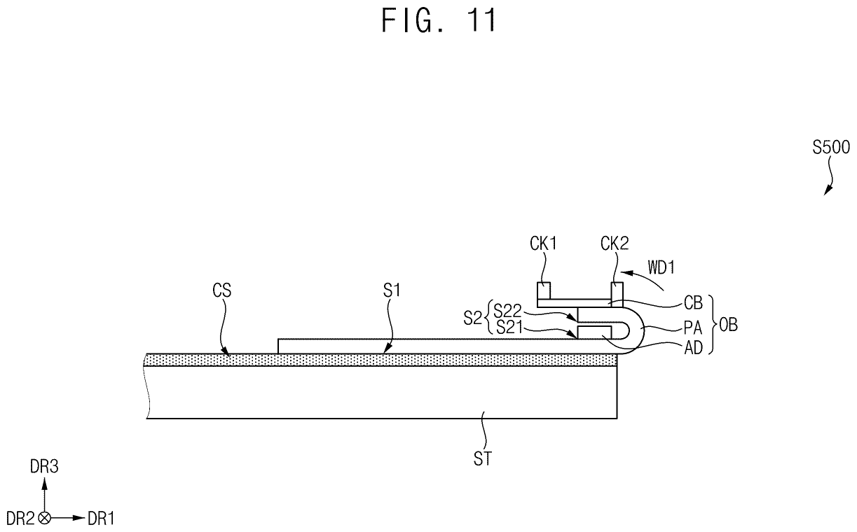

In an embodiment, the first chuck CK1 may chuck the first portion of the circuit board CB (for example, a first portion PA1 of FIG. 4). After the first portion of the circuit board CB is chucked, the first portion may be bent. Accordingly, a position on the circuit board CB may be changed in the third direction DR3 (i.e., from lower part to a top). At this time, the display panel PA may also be moved. Accordingly, a portion of the display panel PA may be bent such that two portions of the second side surface (for example, refer to FIG. 11) face each other. However, the disclosure is not limited to this embodiment.

As described above, the first chuck CK1 may move linearly in the first direction DR1 and/or in the third direction DR3 and may rotate at a selectable angle. However, this is just an example, and a structure of the first chuck CK1 may be changed in various ways.

For example, the first chuck CK1 may further include a pusher. The pusher may be connected to the first chuck CK1 or may be provided as a separate device from the first chuck CK1. For example, the pusher may include a ball screw and a motor connected to the ball screw, a pressurized cylinder. However, the disclosure is not limited thereto.

For example, the pusher may pressurize the object OB. Accordingly, a portion of the second side surface of the display panel PA and a portion of the second side surface of the circuit board CB may be bonded to the adhesive AD.

For example, a second chuck CK2 may be located on the housing HO. The first chuck CK1 and the second chuck CK2 may be located adjacently to each other, as depicted in FIG. 1.

In an embodiment, the second chuck CK1 may chuck a portion of the electronic component and modify a bending shape. For example, the second chuck CK2 may include a second support, a second linear driver, and a second rotator.

For example, the second support may extend in the third direction DR3. For example, the first support and the second support may be the same.

For example, the second linear driver may be connected to the second support and may make a linear motion in one direction (for example, in the first direction DR1, in the second direction DR2, and/or in the third direction DR3). For example, the second linear driver may include a ball screw and a motor connected with the ball screw. However, the disclosure is not limited thereto. For example, the second linear driver may include a pulley and a belt, or the like.

The second rotator may include a second chucking device (for example, a second chucking device PP of FIGS. 4, 5, and 6) and a second rotary device.

In an embodiment, the second chucking device (included in the second chuck CK2) may include a vacuum suctioning pad. The vacuum suctioning pad may vacuum suction a portion of the display panel PA.

However, the disclosure is not limited thereto. For example, a physical chuck (for example, a clamp, or the like.) may be used if there is no risk of physical damage, or an electrostatic chuck may be used if there is no risk such as a short circuit. For example, the second chucking device may avoid a terminal, a pad, a conductor, or the like, formed in the object OB in chucking the object OB.

For example, the second rotator may include a rotary motor and a gear unit connected with the rotary motor, a rotary cylinder, a rotary pulley connected with the rotary motor, a rotary belt connected with the rotary pulley, or the like. However, the disclosure is not limited thereto. For example, the second rotator may modify the bending path.

In an embodiment, the second chuck CK2 may chuck a second portion (for example, a second portion PA2 of FIG. 4) of the display panel PA. For example, if the display panel PA and the circuit board CB are connected by a film (the COF method), the second chuck CK2 may chuck the film.

For example, the first chuck CK1 and the second chuck CK2 may proceed with the bending process while minimizing a risk of cracking. In case that the second portion of the display panel PA is chucked, the object OB may be bent by the first chuck CK1. Thereafter, the second chuck CK2 may move and modify a shape of the first bending portion and/or the second bending portion.

As described above, the second chuck CK2 may move linearly in the first direction DR1 and/or in the third direction DR3 and may rotate at a selectable angle. In addition, the second chuck CK2 may also be driven using the first chuck CK1 or controlled separately using the first chuck CK1. However, this is an example, and a structure of the second chuck CK2 may be changed.

For example, the second chuck CK2 may further include a damper. The damper may include a cylinder, or the like. The cylinder may dampen the bending portion (for example, the first bending portion and/or the second bending portion) when a certain force is applied. However, the disclosure is not limited thereto. The damper may include a variety of devices.

The driver DRS can be located between the housing HO and the stage ST. For example, the driver DRS may move the stage ST in one direction (for example, in the first direction DR1). For example, the driver DRS may include a ball screw and a motor connected to the ball screw, a linear motor, a variable cylinder, or the like.

The aligner AL may be located on the stage ST. For example, the aligner AL may adjust the position of the stage ST. For example, the aligner AL may move the stage ST in the first direction DR1 and/or in the second direction DR2. Through the aligner AL, the stage ST may be linearly moved in the first direction DR1 and/or the second direction DR2, or may be rotated. For example, the aligner AL may include a motor, a cylinder, or the like.

For example, the first sensor VI1 may be located on the movement path of the stage ST. For example, the first sensor VI1 may be located between an initial position of the stage ST and the first chuck CK1. The first sensor VI1 may detect a first position of the object OB on the stage ST. For example, the first sensor VI1 may include a CCD, a camera, or the like.

For example, the second sensor VI2 may be spaced apart from the first chuck CK1 in the third direction DR3. The second sensor VI2 may detect a position of the object OB under the first chuck CK1. For example, the second sensor VI2 may include a CCD, camera, or the like.

For example, the first sensor VI1 and the second sensor VI2 may be the same type of device, or they may be different devices.

For example, the first sensor VI1 may detect the first position of the object OB on the stage ST through a first alignment mark A1 formed on the display panel PA. For example, the first alignment mark A1 may be formed on the display panel PA.

After alignment based on first alignment mark A1, the object OB may be moved towards the first chuck CK1. At this time, the driver DRS may move the stage ST so that the object OB may be adjacent to the first chuck CK1. However, the disclosure is not limited thereto. For example, the stage ST may be fixed, and the first chuck CK1 may move.

For example, the second sensor VI2 may detect a position of the object OB under the first chuck CK1 through a second alignment mark A2 formed on the display panel PA. For example, the second alignment mark A2 may be formed on the circuit board CB.

The second alignment mark A2 allows a positioning accuracy of the bending adhesion process to be determined. For example, if the second alignment mark A2 is located within a selectable range compared to a reference align mark, the bending adhesion process may be determined to have been performed at a correct location. However, if the second alignment mark A2 is located outside the selectable range upon comparison with the reference align mark, the bending adhesion process may be determined to have been performed in a wrong position, leading to poor adhesion. In an event of the poor adhesion, a breakage or damage of the electronic component due to a concentration of stress after the bending may occur.

In an embodiment, the third sensor VI3 and the fourth sensor VI4 may be located to photograph the side surface of the bending portion (for example, the first bending portion and the second bending portion). In an embodiment, the third sensor VI3 and the fourth sensor VI4 may include a CCD, camera, or the like.

For example, a third sensor VI3 and a fourth sensor VI4 may be connected to a stage ST and may move with the stage ST.

For example, the third sensor VI3 and the fourth sensor VI4 may be located on opposite sides of the stage ST (i.e., left and right sides). The third sensor VI3 and the fourth sensor VI4 may detect a portion of the object OB (refer to FIGS. 4, 5, and 6). For example, after bending the object OB, the left and right sides may end up with different shapes. In this case, the left and right sides are controlled independently using the third sensor VI3 and the fourth sensor VI4, which may photograph the left and right sides of the bending portion.

Detailed descriptions of the third sensor VI3 and fourth sensor VI4 will be described below with reference to FIGS. 4, 5, and 6.

The controller CO may control the operations of the first sensor VI1, the second sensor VI2, the third sensor VI3, the fourth sensor VI4, the stage ST, the first chuck CK1, and the second chuck CK2.

For example, the controller CO may be equipped with a separate device, or it may be embedded in the device in the form of a computer program, or the like. However, the disclosure is not limited to any particular form of the controller CO.

In an embodiment, the controller CO may control the first sensor VI1, the second sensor VI2, the third sensor VI3, and the fourth sensor VI4 to generate an input image. In addition, the controller CO may independently control the operation of the stage ST, the first chuck CK1, and the second chuck CK2 by providing the input image. For example, the controller CO may linearly drive the stage ST, the first chuck CK1, and the second chuck CK2. For example, the controller CO may control the first chuck CK1 and the second chuck CK2 to be driven at the same time. In another embodiment, the controller CO may be controlled so that only the second chuck CK2 is driven.

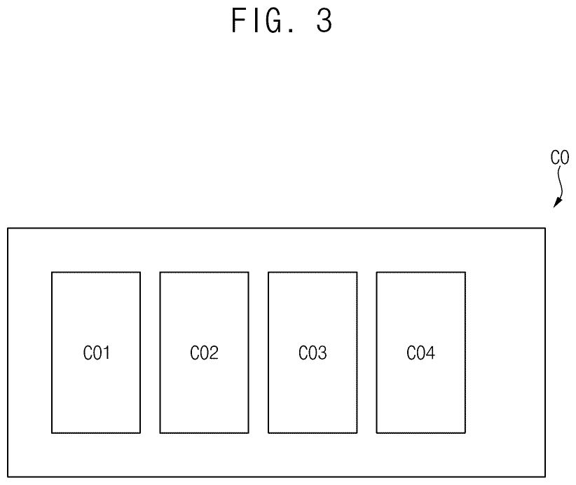

Detailed descriptions of the controller CO will be described below with reference to FIG. 3.

FIGS. 1 and 2 are examples, and the disclosure is not limited to what is explicitly disclosed in FIGS. 1 and 2. For example, the manufacturing device for the display device 1 may include more component(s), or all or part of the component may be omitted/substituted.

For example, in FIG. 1, the bending arm BA is described to include the first chuck CK1 and the second chuck CK2; however, the disclosure is not limited thereto. For example, the bending arm BA undergoing the bending process may include only the first chuck CK1, and the second chuck CK2 may include of a separate device. In this case, after proceeding with the bending process using the bending arm BA, the shape of the bending portion may be modified by the second chuck CK2 (by moving the chamber). In another embodiment, the bending arm BA that proceeds with the bending process may include the first chuck CK1, and the second chuck CK2 may be provided separately (in a same chamber). In this case, after completing the bending process and the shape modification process of the bending portion, the object OB may be moved to another chamber. However, the disclosure is not limited thereto.

FIG. 3 is a block view illustrating the controller included in the manufacturing device for the display device of FIG. 1.

Referring to FIGS. 1, 2, and 3, in an embodiment, the controller CO may include the first controller CO1, the second controller CO2, the third controller CO3, and the fourth controller CO4.

For example, in case that the controller CO is provided in the form of the program, the first controller CO1, the second controller CO2, the third controller CO3, and the fourth controller CO4 may each function to implement the program. However, the disclosure is not limited thereto.

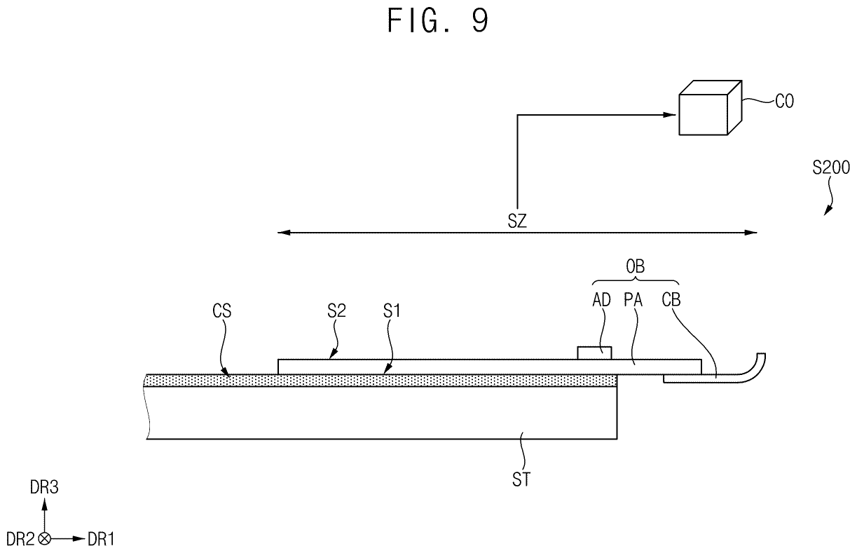

In an embodiment, the first controller CO1 may input the dimension of the object OB (for example, a dimension SZ of FIG. 9) and generate the movement paths of the first chuck CK1 and the second chuck CK2 based on the dimension.

In the manufacturing device for the display device according to a first comparative embodiment, the display panel PA may be fixed to the stage ST, the first chuck CK1 may chuck the circuit board CB, and the circuit board CB may be bent to achieve the bending shape of the object OB. In this case, the bending shape (for example, a size and a position of a bending radius) may be indirectly controlled by the first chuck CK1. The bending shape is not controlled without using the first chuck CK1.

In the manufacturing device for the display device according to a second comparative embodiment, the device may control the size of the bending radius. For example, the display panel PA may be fixed to the stage ST, the first chuck CK1 may chuck the circuit board CB, and the circuit board CB may be bent to achieve the desired bending shape of the object OB. At this time, the size of the bending radius may be different in a beginning bending state and an end of the bending state as the first chuck CK1 is linearly driven. For example, the bending radius may be smaller after the bending than before the bending.

In the manufacturing device for the display device according to a third comparative embodiment, the device may control the bending shape. For example, the bending shape may be implemented on the stage ST. For example, the bending shape may have an ‘L’ shape. However, the disclosure is not limited thereto. For example, the display panel PA may be fixed to the stage ST, the first chuck CK1 may chuck the circuit board CB, the circuit board CB may be bent and located on the display panel PA and pressurized. At this time, the bending shape is pre-implemented in the stage ST, so that the portion where the display panel PA and the circuit board CB are pressurized may have the same/similar form to the pre-implemented bending shape.

The manufacturing device for the display device according to the comparative embodiment could not directly control the bending shape. For example, the bending shape may be formed indirectly by the bending process (for example, by means of the linear driver and/or the rotator according to a RΘ coordinate system), or the bending shape may be implemented before the object OB is placed on the stage ST.

The manufacturing device of the display device according to an embodiment of the disclosure may implement the bending shape using the first chuck CK1 and precisely control the bending shape (for example, the bending radius, position, or the like) using the second chuck CK2 to manufacture the bezel-less display device with reduced dead space.

For example, if the second chuck CK2 has a chucked portion of the display panel PA, the bending shape may be further modified after the bending process. For example, as the bending process progresses, the bending shape may be modified so that the bending radius is fine-tuned (e.g., made smaller).

For example, the second chuck CK2 may use two linear drives and one rotator according to a YZΘ coordinate system. For example, the bending trajectory may include N segments (for example, the N is a natural number of 2 or more). The first controller CO1 may control a length, a direction, or the like of each segment of the bending shape more precisely. Therefore, A variety of bending trajectories may be realized using a single device, and display devices with multiple dimensions may be manufactured.

In an embodiment, the second controller CO2 may determine whether the alignment error of the display panel PA and circuit board CB satisfies the first reference range. For example, if the alignment error satisfies the first reference range, it is determined to meet the quality standards. If the alignment error is outside the first reference range, it may be determined to be a defective product. For example, the alignment error is a tolerance of a material itself, attachment process of tolerances in the display panel PA and circuit board CB may vary from object OB.

For example, the alignment error may be determined based on the first alignment mark A1, the second alignment mark A2, the first sensor VI1 photographing the first alignment mark A1, and the second sensor VI2 photographing the second alignment mark A2.

In an embodiment, the third controller CO3 may determine whether the bending error, including the shape error and position error of the bending portion, which is the portion where the object OB is bent, satisfies the second reference range. For example, the bezel may also be referred to as the dead space. The dead space may mean an area where the pixels are not located. The second reference range may include the size, location, or the like, of the bezel. For example, if the bending error satisfies the second reference range, it is determined to meet the quality standard. On the other hand, if the bending error is outside the second reference range, it may be determined to be defective. For example, the bending portion may also be included in the dead space where the pixel is not located.

For example, the bending error may be determined using the third sensor VI3 and the fourth sensor VI4. For example, the third sensor VI3 and the fourth sensor VI4 may be vision cameras that photograph the bend portion from the side surface.

The third sensor VI3 and the fourth sensor VI4 may check the bending shape in real time, allowing the bending shape to be controlled precisely.

In an embodiment, the fourth controller CO4 may compare the alignment error and the bending error.

For example, the alignment error and the bending error may be in a trade-off relationship. For example, if the second chuck CK2 is moved to reduce the bending error, the alignment error may be greater. The greater a movement of the second chuck CK2 is, the greater the alignment error may be.

In order to reduce the dead space and at the same time minimize the alignment error in the display device, the second chuck CK2 may modify the bending shape only if the alignment error is less or greater than the bending error.

FIGS. 4, 5, and 6 are views illustrating the images taken by the camera included in the manufacturing device for the display device of FIGS. 1 and 2.

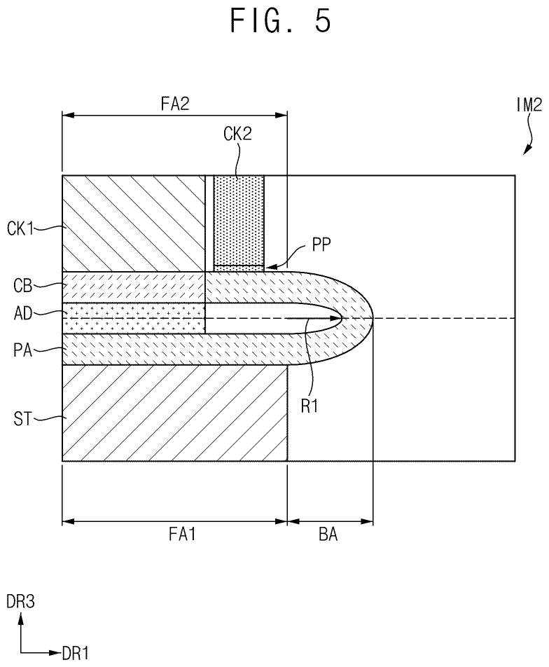

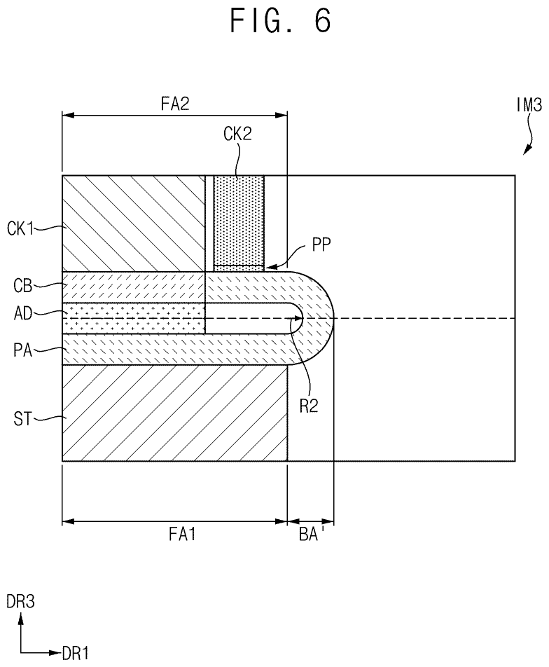

For example, FIGS. 4, 5, and 6 may be input images acquired by either of the third sensor VI3 and the fourth sensor VI4 included in FIG. 2. For example, a first input image IM1 of FIG. 4 may be the input image acquired before bending the object OB, and a second input image IM2 of FIG. 5 may be the input image acquired after bending the object OB with the first chuck CK1, and the third input image IM3 of FIG. 6 may be the input image acquired after modifying the bending shape using the second chuck CK2.

Referring to FIGS. 2 and 4, in an embodiment, the object OB may include the display panel PA, the circuit board CB, and the adhesive AD on the display panel PA. For example, the adhesive AD may be located on the display panel PA.

For example, the adhesive AD may be disposed in various ways depending on a size of the electronic component. For example, the adhesive AD may be located only on a portion of the display panel PA.

For example, the adhesive AD may include a pressure-sensitive adhesive. For example, the pressure-sensitive adhesive may include an optically clear adhesive. The pressure-sensitive adhesive may be a material which, when pressure is applied to an adhesive surface, acts as an adhesive material. The optical adhesive may be a kind of pressure-sensitive adhesive. A structure with the optical adhesive may improve visibility by minimizing changes caused by the reflection and refraction of light at layers of different materials, compared to an air gap structure (i.e., a structure filled with air).

For example, the optical adhesive may include both a UV adhesive and a normal adhesive. A UV adhesive may be an adhesive whose modulus increases through UV curing, and the normal adhesive may be an adhesive having a high modulus without requiring the UV curing. However, the disclosure is not limited thereto.

In an embodiment, the object OB may be divided into a first flat portion FA1, a second flat portion FA2, and a bending portion (BA, BA'). For example, before the object OB is bent, the first flat portion FA1, the second flat portion FA2, and the bending portion BA may be located on substantially the same plane. The first flat portion FA1 may be included in the display panel PA. The second flat portion FA2 may be included in the circuit board CB. The bending portion BA may be located between the first flat portion FA1 and the second flat portion FA2.

For example, a portion of the object OB may be located on the stage ST and remainder of the object OB may be spaced apart from the stage ST. For example, a portion of the first flat portion FA1 of the display panel PA may be in contact with the stage ST, and the remainder of the first flat portion FA1 and the circuit board CB might not be in contact with the stage ST.

In an embodiment, the first chuck CK1 may chuck a first portion PA1 of the circuit board CB. The second chuck CK2 may chuck a second portion PA2 of the display panel PA.

Referring to FIG. 5, in an embodiment, after the object OB has been bent, the first flat portion FA1 and the second flat portion FA2 overlap each other in one direction (for example, the third direction DR3). The bending portion BA may have a first radius R1.

Referring to FIG. 6, in an embodiment, if the bending error is outside the second reference range, the second chuck CK2 may move in the direction of reducing the bending error. For example, the second chuck CK2 may move in a reverse direction first direction DR1 (referring to FIG. 6, to the left). Accordingly, the bending portion BA′ may have a second radius R2 smaller than the first radius R1 of FIG. 5.

The manufacturing device for the display device 1 of FIGS. 1 and 2 may be applied to a variety of objects OB. For example, the object OB may include the display panel PA, a cushion layer that protects the back of the display panel PA, and the adhesive AD that bonds the display panel PA to the cushion layer. For example, the object OB may include the display panel PA, a fingerprint sensor located on the display panel PA, and the adhesive AD that bonds the fingerprint sensor to the display panel PA. For example, the object OB may include the display panel PA, a mold that surrounds an outer edge of the display panel PA, and the adhesive AD that bonds the display panel PA to the mold.

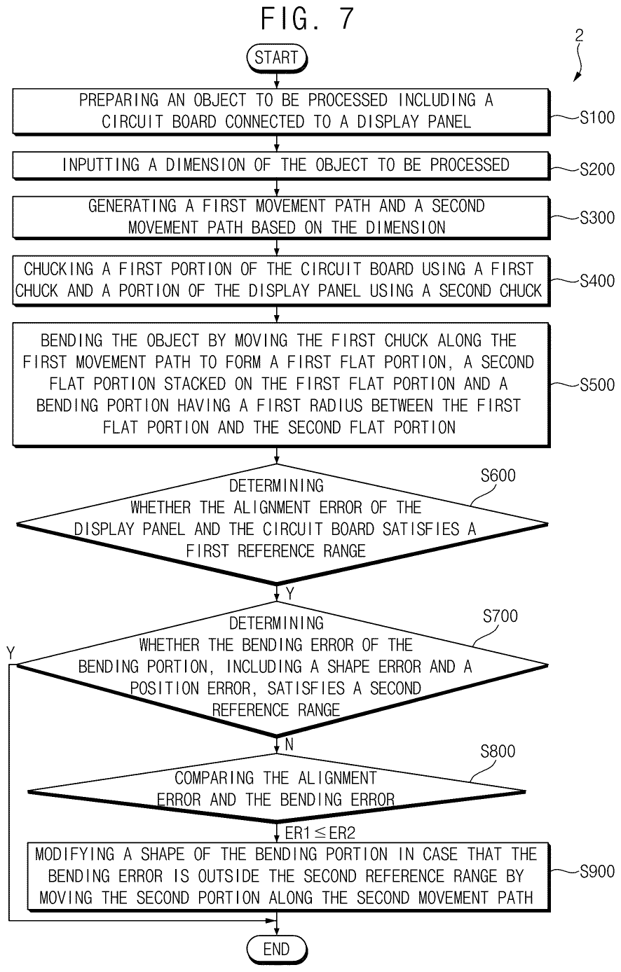

FIG. 7 is a flow chart illustrating the manufacturing method of the display device according to an embodiment of the disclosure. FIGS. 8, 9, 10, 11, 12, 13, 14, and 15 are views illustrating the manufacturing method of the display device of FIG. 7.

Hereinafter, for convenience of explanation, redundant descriptions of the manufacturing device for the display device with reference to FIGS. 1, 2, 3, 4, 5, and 6 will be omitted or simplified.

Referring to FIGS. 1, 2, 7, and 8, the object OB including the circuit board CB connected to the display panel PA may be prepared (S100).

The manufacturing device of the display device 1 of FIGS. 1 and 2 may include the bending device. Before the bending process using the bending device, the circuit board CB may be pre-connected to the display panel PA. For example, the display panel PA and the circuit board CB may be connected in the COF method. However, the disclosure is not limited thereto. In addition, the adhesive AD may also be pre-located on the display panel PA.

The object OB may be located on the stage ST. The object OB may include the first side surface S1 and the second side surface S2 that are opposite surfaces of a component (for example, separated in the third direction DR3). A portion of the first side surface S1 (for example, a portion of the display panel PA) may be in contact with the stage ST, and another portion of the first side surface S1 may be in contact with the circuit board CB).

Referring to FIGS. 1, 2, 4, 5, 7, 9, and 10, in an embodiment, the dimension SZ of the object OB may be inputted, and the first movement path WD1 and a second movement path (for example, a second movement path WD2 of the object OB may be generated based on the dimension SZ of the object OB (S200, S300). In an embodiment, a portion of the circuit board CB may be chucked, and a portion of the display panel PA may be chucked. Specifically, the first portion PA1 of the circuit board CB may be chucked by the first chuck CK1, and the second portion PA2 of the display panel PA may be chucked by the second chuck CK2 as depicted in FIG. 4 (S400).

The manufacturing method and device for the display device according to a comparative embodiment can not directly control the bending shape. In the comparative embodiment, the bending shape may be controlled indirectly by the bending process, or the bending shape may be achieved on the stage ST before the bending process. Accordingly, if the dimension SZ of the object OB changes, the update would not be reflected in the comparative embodiment.

The manufacturing method of the display device according to an embodiment of the disclosure may achieve the bending shape using the first chuck CK1 and may fine tune the bending shape (for example, the bending radius, position, or the like.) using the second chuck CK2 to manufacture the bezel-less display device with reduced dead space. The manufacturing method of the display device according to an embodiment of the disclosure may set the first movement path WD1 and the second movement path based on the dimension SZ of the object OB. Accordingly, various bending trajectories may be achieved.

The first movement path WD1 may be the path of the first chuck CK1. In other words, the first movement path WD1 may be the path that the first chuck CK1 travels to form the bending portion BA.

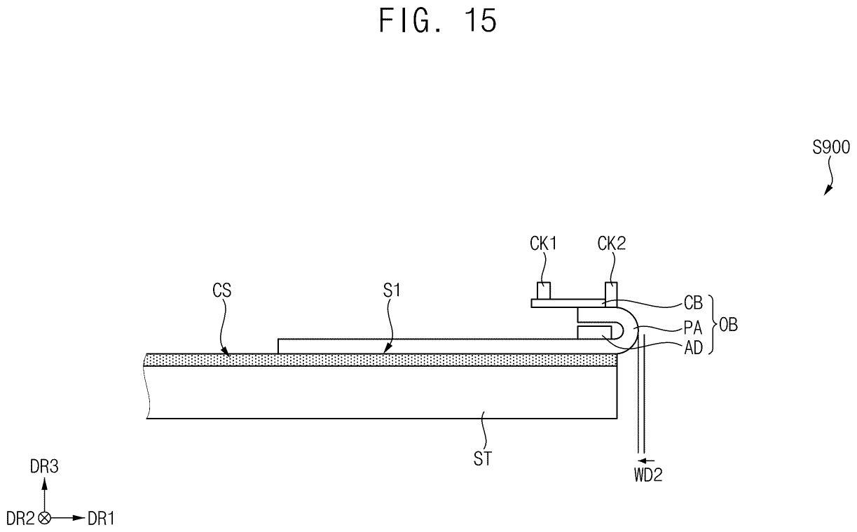

The second movement path WD2 (see FIG. 15) may be the movement path of the second chuck CK2. In other words, the second movement path may be the path that the second chuck CK2 travels to modify the shape of the bending portion (i.e., the bending shape). For example, the shape of the bending portion BA of FIG. 5 may be modified to achieve the shape of the bending portion BA′ of FIG. 6.

As described above, in an embodiment, the first movement path WD1 and/or the second movement path WD2 may include a plurality of segments. The manufacturing method of the display device according to an embodiment of the disclosure may independently control the size, position, or the like, of each of the plural segments. Accordingly, the shape of the bending portion may be controlled more precisely.

As described above, in an embodiment, the portion of the display panel PA may be vacuum-suctioned.

Referring to FIGS. 1, 2, 4, 5, 7, and 11, in an embodiment, the object OB may be bent to form the first flat portion FA1, the second flat portion FA2 facing the first flat portion FA1 in one direction (for example, the third direction DR3), and the bending portion BA having the first radius R1 and connecting the first flat portion FA1 to the second flat portion FA2. Specifically, the first chuck CK1 may bend the object OB so that the first flat portion FA1 and the second flat portion FA2 are stacked in one direction (for example, the third direction DR3), and the bending portion BA having the first radius R1 connects the first flat portion FA1 and the second flat portion FA2 (S500). The first chuck CK1 may move along the first movement path WD1.

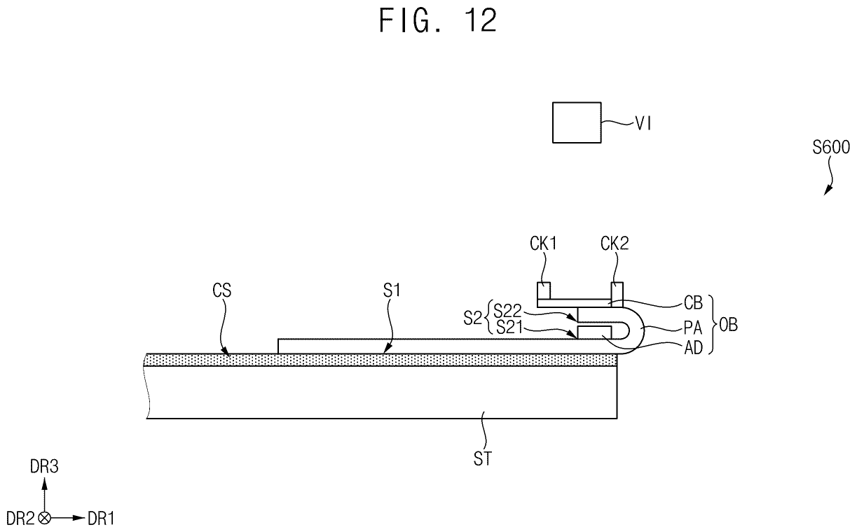

For example, the first chuck CK1 may bend the object OB so that a portion of the second side surface S2 of the object OB (for example, a first surface portion S21 of the second side surface of the display panel PA depicted in FIG. 12) and the remainder of the second side surface S2 of the object OB (for example, a second surface portion S22 of the second side surface of the display panel PA and the circuit board CB) may be stacked in the third direction DR3. The adhesive AD may be located between the first surface portion S21 of the second side surface S2 and the second surface portion S22 of the second side surface S2.

As shown in FIGS. 4 and 5, before the object OB is bent, the first flat portion FA1, the bending portion BA, and the second flat portion FA2 of the object OB may have extended in one direction (for example, the first direction DR1), and after the object OB is bent, the first flat portion FA1 and the second flat portion FA2 may be located in the direction that crosses the one direction (for example, the third direction DR3), and between the first flat portion FA1 and the second flat portion FA2, the bending portion BA may have the first radius R1.

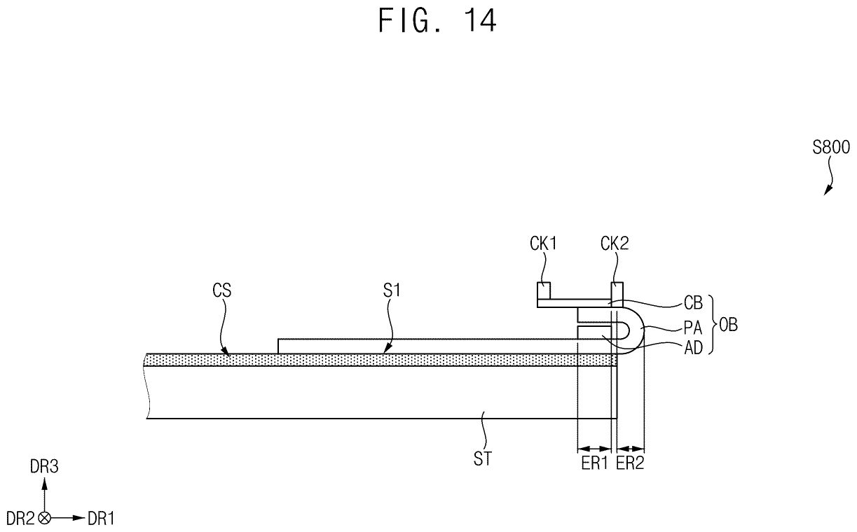

Referring to FIGS. 1, 2, 7, and 12, in an embodiment, whether the alignment error of the display panel PA and the circuit board CB (for example, an alignment error ER1 of FIG. 14) satisfies the first reference range may be determined (S600).

The alignment error may include the position error of the display panel PA, the position error of the circuit board CB, or the like.

For example, the alignment error may be identified by the vision camera VI. For example, the vision camera VI of FIG. 12 may correspond to the first sensor VI1 and the second sensor VI2 of FIGS. 1 and 2.

For example, if the alignment error is outside the range of the first reference range, the display device under manufacture is determined to be defective, and the subsequent process might not be carried out.

Referring to FIGS. 1, 2, 7, and 13, in an embodiment, if the alignment error satisfies the first reference range, the bending error (for example, a bending error ER2 of FIG. 14) may be determined to satisfy the second reference range (S700).

In more detail, if the alignment error satisfies the first reference range, for example, the size error of the bending radius of the bending portion, the shape error of the bending portion, the position error of the bending portion, or the like, may be used to determine whether the bending error satisfies the second reference range.

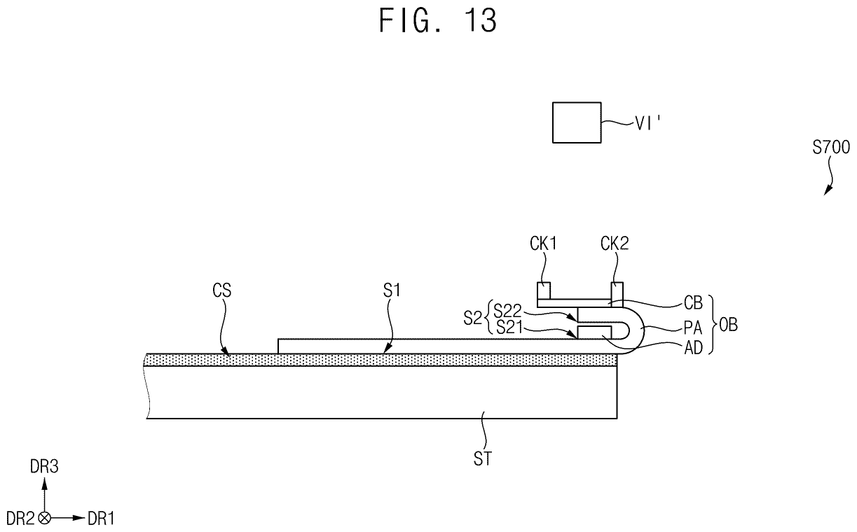

In an embodiment, the bending error may be determined based on the image taken from the side of the bending portion. In an embodiment, the bending error may be identified by a vision camera VI′. For example, the vision camera VI′ of FIG. 13 may correspond to the third sensor VI3 and the fourth sensor VI4 of FIGS. 1 and 2.

If the bending error satisfies the second reference range, the bending process may terminate.

Referring to FIG. 14, in an embodiment, the alignment error ER1 and the bending error ER2 may be compared (S800).

If the bending error is outside the second reference range, the bending shape may be modified by comparing the alignment error ER1 and the bending error ER2.

In an embodiment, if the alignment error ER1 is smaller than or equal to the bending error ER2, the bending shape may be modified.

As mentioned above, the alignment error ER1 and the bending error ER2 may have a trade-off relationship. For example, if the second chuck CK2 is moved in one direction (for example, in the reverse direction of the first direction DR1) to reduce the bending error ER2, the alignment error ER1 may increase. If the alignment error ER1 is outside the first reference range, the display device may be determined to be defective. Thus, the manufacturing method of the display device according to an embodiment of the disclosure may modify the bending shape to reduce the dead space if the alignment error ER1 is smaller than or equal to the bending error ER2.

If the alignment error ER1 is greater than the bending error ER2, the display device under manufacture may be determined to be defective and the manufacturing process might be aborted.

Referring to FIG. 15, in an embodiment, if the bending error ER2 is outside the second reference range, the bending shape may be modified. Specifically, if the bending error ER2 is outside the second reference range, the second chuck CK2 may move to modify the bending shape (S900).

For example, the second chuck CK2 may move in one direction (for example, in the reverse direction of the first direction DR1). The second movement path WD2 of the second chuck CK2 may be set based on a type, size, alignment error ER1, bending error ER2, or the like of the object OB. Accordingly, the bending portion has the second radius (the second radius R2 of FIG. 5) smaller than the first radius (the first radius of FIG. 4).

For example, if the first chuck CK1 and the second chuck CK2 may be connected to one support, the first chuck CK1 and the second chuck CK2 may be driven simultaneously when bent (refer to FIG. 11). However, when modifying the bending shape, the first chuck CK1 is fixed, and the second chuck CK2 may be moved. Since the second chuck CK2 is independently controlled, the shape of the bending portion (BA, BA′) may be directly and independently controlled (refer to FIG. 15).

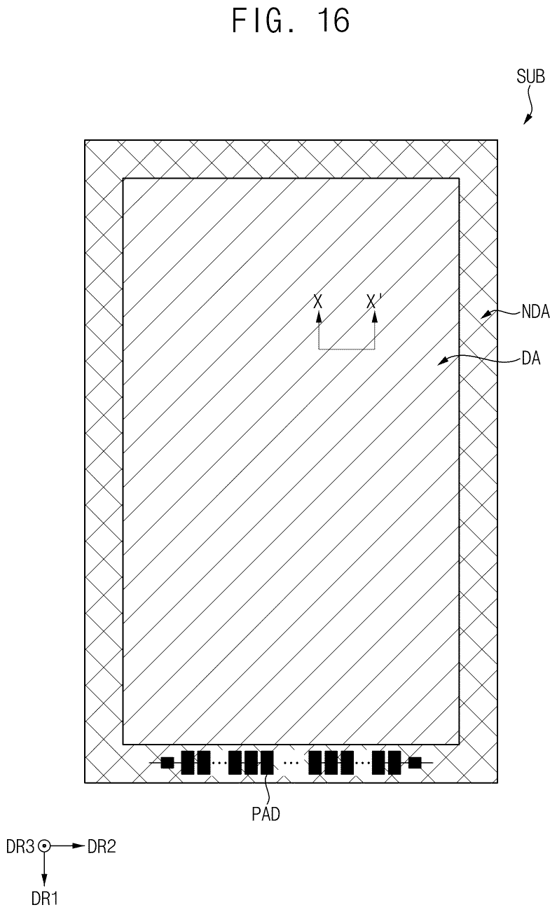

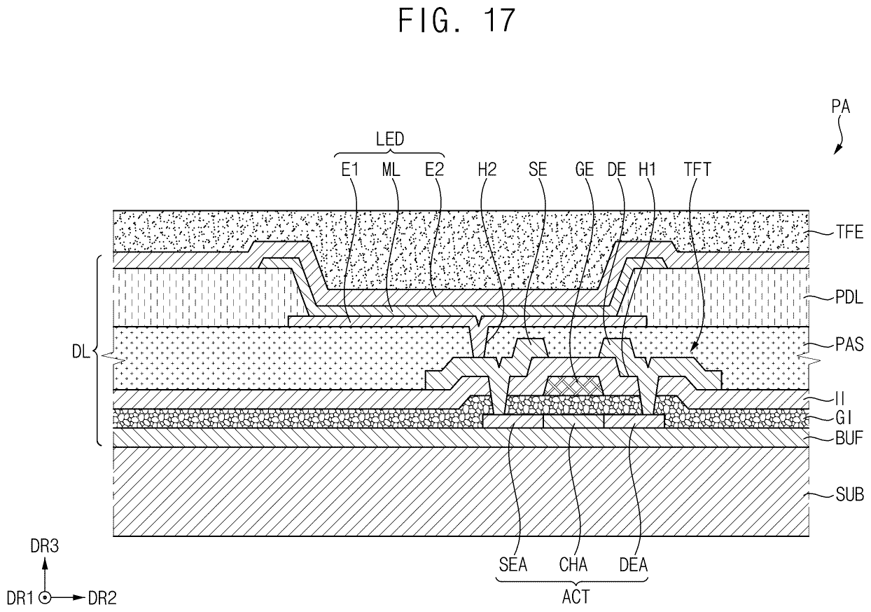

FIG. 16 is a top view of the display panel of the display device manufactured using the manufacturing device for the display device of FIG. 1 and manufacturing method of the display device of FIG. 7. FIG. 17 is a cross-sectional view taken along X-X′ line of FIG. 16.

Referring to FIGS. 16 and 17, the display panel PA may include a plurality of layers on a base substrate SUB. The PAD may be a part where the display panel PA and the circuit board of FIG. 1 are connected. For example, a pixel included in the display panel PA may include the base substrate SUB, a buffer layer BUF, a displaying layer DL, and an encapsulation layer TFE.

The displaying layer DL may include a transistor TFT, a gate insulating layer GI, an interlayer insulating layer II, a passivation layer PAS, a light-emitting element LED, and a pixel defining layer PDL.

A display area DA may include a light-emitting region and a non-light-emitting region. For example, the transistor TFT and the light-emitting elements LED may be located in the light-emitting region.

For example, the transistor TFT may include an active layer ACT, a gate electrode GE, a source electrode SE, and a drain electrode DE. The light-emitting element LED may include a first electrode E1, an intermediate layer ML, and a second electrode E2.

The non-light-emitting region may surround the light-emitting region in plan view. Here, “plan view”may mean a view along the third direction DR3.

The base substrate SUB may include glass, quartz, plastic, SUS, titanium (“Ti”), or the like. For example, the base substrate SUB may have flexible, bend-able, or roll-able properties.

The buffer layer BUF may be disposed on the base substrate SUB. The buffer layer BUF may include an inorganic insulating material. For example, the buffer layer BUF may include silicon oxide, silicon nitride, silicon oxide, or the like. The buffer layer BUF may prevent an impurity from diffusing into or damaging the active layer ACT of the transistor TFT. However, the disclosure is not limited thereto. For example, the buffer layer BUF may include an organic insulating material.

The active layer ACT may be disposed on the buffer layer BUF. According to an embodiment, the active layer ACT may include a silicon semiconductor material. For example, the active layer ACT may include amorphous silicon, polycrystalline silicon, or the like. According to an embodiment, the active layer ACT may include oxide semiconductor material. For example, the active layer ACT may include zinc oxide, zinc-tin oxide, zinc-indium-oxide, indium-oxide, titanium-oxide, indium-gallium-zinc-oxide, indium-zinc-tin-oxide, or the like. According to an embodiment, the active layer ACT may include an organic semiconductor material.

The active layer ACT may include a source region SEA, a drain region DEA, and a channel region CHA that is interposed between the source region SEA and the drain region DEA.

For example, the active layer ACT may be formed by disposing an amorphous silicon layer on the buffer layer BUF, crystallizing the amorphous silicon layer, and patterning the crystallized silicon layer. For example, the active layer ACT may be doped with impurities in the source region SEA and drain region DEA, depending on a type of TFT (for example, driving TFT, switching TFT, or the like).

The gate insulating layer GI may be disposed on the active layer ACT. The gate insulating layer GI may include an inorganic insulating material. For example, the gate insulating layer GI may include silicon oxide, silicon nitride, silicon oxide, titanium-oxide, tantalum oxide, or the like. The gate insulating layer GI may electrically insulate the active layer ACT from the gate electrode GE from each other.

The gate electrode GE may be disposed on the gate insulating layer GI. The gate electrode GE may include a conductive material. For example, the gate electrodes GE may include a metal, an alloy, a conductive metal oxide, a transparent conductive material, or the like. The gate electrodes GE may be applied with a gate signal. The gate signal may turn on/off the transistor TFT to adjust an electrical conductivity of the active layer ACT.

The interlayer insulating layer II may be disposed on the gate electrode GE. The interlayer insulating layer II may include an organic and/or an inorganic insulating material. The interlayer insulating layer II may electrically insulate the source electrode SE and the drain electrode DE from the gate electrode GE.

The source electrode SE and drain electrode DE may be disposed on the interlayer insulating layer II. The source electrode SE and the drain electrode DE may include a conductive material. For example, the source electrode SE and the drain electrode DE may include a metal, an alloy, a conductive metal oxide, a transparent conductive material, or the like.

The source electrode SE and drain electrode DE may be in electrical contact with the active layer ACT through a contact hole H1 that passes through the interlayer insulating layer II and the gate insulating layer GI. For example, the source electrode SE may be connected to the source region SEA and the drain electrode DE may be connected to the drain region DA through a contact hole H1 in the interlayer insulating layer II and gate electrode GE.

The passivation layer PAS may be disposed on the source electrode SE and the drain electrode DE. The passivation layer PAS may include an organic insulating material. For example, the passivation layer PAS may include a polyacrylic resin, a polyimide-based resin, an acrylic-based resin, or the like. A top surface of the passivation layer PAS may be substantially flat. For example, the passivation layer PAS may be formed with a transparent insulator to achieve a resonant effect. For example, the passivation layer PAS may include two or more layers including organic and/or inorganic matter. However, the disclosure is not limited thereto.

For another embodiment, the top surface of the passivation layer PAS may be formed to bend according to a curvature of an underlying layer. In this case, the passivation layer PAS may also include an inorganic insulating material.

The first electrode E1 may be disposed on the passivation layer PAS. The first electrode E1 may include a conductive material. For example, the first electrode E1 may include a metal, an alloy, a conductive metal oxide, a transparent conductive material, or the like.

The first electrode E1 may be electrically connected to the source electrode SE or the drain electrode DE through a contact hole H2 that passes through the passivation layer PAS. According to an embodiment, the first electrode E1 may be referred to as an anode electrode.

The pixel defining layer PDL may be disposed on the passivation layer PAS and cover a portion of the first electrode E1. The pixel defining layer PDL may include an organic insulating material. For example, the pixel defining layer PDL may include a polyacrylic compound, a polyimide-based compound, or the like. The pixel defining layer PDL may including a pixel opening to partition the light-emitting region of the pixel. The pixel opening defined in the pixel defining layer PDL may extend to the first electrode E1.

The intermediate layer ML may be disposed on the first electrode E1 in the pixel opening. The intermediate layer ML may include an organic light-emitting material. According to an embodiment, the intermediate layer ML may have a multi-layered structure including various functional layers. For example, the intermediate layer ML may include at least one of a hole injection layer, a hole transport layer, an electron transport layer, or an electron injection layer.

The second electrode CE may be disposed on the intermediate layer ML and cover the pixel defining layer PDL. According to an embodiment, the second electrode CE may be referred to as a cathode electrode.

In addition, the intermediate layer ML and the second electrode E2 may be formed on the first electrode E1.

The first electrode E1 and the second electrode E2 may be separated from each other by the intermediate layer ML, and light may be emitted from the organic light-emitting layer by applying voltages of different polarities to the intermediate layer ML. On the other hand, a unit pixel may include a plurality of sub pixels, and the plurality of sub pixels may emit light of various colors. For example, each of the plurality of sub pixels may emit any one of red, green, or blue lights. However, the disclosure is not limited thereto. For example, the plurality of sub pixels may emit white light.

The encapsulation layer TFE may have a multi-layered structure. For example, the encapsulation layer TFE may include at least one organic layer interposed between at least two inorganic layers. For example, the encapsulation layer TFE may include at least one inorganic layer interposed between at least two organic layers. For example, the encapsulation layer TFE may include at least an organic layer interposed between at least two inorganic layers, and at least an inorganic layer interposed between at least two organic layers.

For example, the encapsulation layer TFE may include an organic layer. For example, the organic layer may include a polymer. For example, the polymer may include polyethylene terephthalate, polyimide, polycarbonate, epoxy, polyethylene, polyacrylate, or the like. Each of them may be used alone or in combination with each other. However, the disclosure is not limited thereto. The organic layer may include a material polymerized monomer composition. For example, the monomer composition may include a mono-acrylate-based monomer, a de-acrylate-based monomer, a tri-acrylate-based monomer, a photo-initiator such as TPO (2,4,6-tri-methylbenzoyl-diphenyl phosphine oxide), or the like. Each of them may be used alone or in combination with each other. However, the disclosure is not limited thereto.

For example, the encapsulation layer TFE may include an inorganic layer. For example, the inorganic layer may include a metal oxide or a metal nitride. For example, the inorganic layer may include SiNₓ, Al₂O₃, SiO₂, TiO₂, or the like. Each of them may be used alone or in combination with each other. However, the disclosure is not limited thereto.

For example, the encapsulation layer TFE may include a first inorganic layer, a first organic layer, and a second inorganic layer sequentially stacked from a top of the light-emitting element LED. For example, the encapsulation layer TFE may include the first inorganic layer, the first organic layer, the second inorganic layer, a second organic layer, and a third inorganic layer sequentially stacked from the top of the light-emitting element LED. For example, the encapsulation layer TFE may include the first inorganic layer, the first organic layer, the second inorganic layer, the second organic layer, the third inorganic layer, a third organic layer, and the fourth inorganic layer sequentially stacked from the top of the light-emitting element LED.

A top layer of the encapsulation layer TFE that is the outermost layer of the display panel PA may be formed with the inorganic layer to prevent the moisture permeation into the light-emitting element LED. However, the disclosure is not limited thereto.

A halide-metal layer may be further included between the light-emitting element LED and the first inorganic layer. For example, the halide-metal layer may include lithium fluoride (“LiF”). In case that the forming of the first inorganic layer by sputtering method, the halide-metal layer may prevent the light-emitting element LED from being damaged. However, the disclosure is not limited thereto.

The manufacturing device for the display device according to an embodiment of the disclosure may be applied to a manufacturing process of the display device used in a computer, a laptop, a mobile phone, a smartphone, a smart pad, a PMP, a PDA, a MP3 player, or the like.

Although the above has been explained with reference to embodiments of the disclosure, it will be understood that a person with ordinary knowledge in the field of technology may modify and change the disclosure in various ways without materially departing from the novel teaching and advantages of the disclosure. Accordingly, it will be understood that all such modifications are intended to be included within the scope of the disclosure as defined in the following claims.

What is claimed is:

1. A manufacturing device for a display device that includes an object having a display panel and a circuit board connected to the display panel, the manufacturing device comprising:
a first chuck that chucks the circuit board and bends the object ; and
a second chuck that chucks the display panel.

2. The manufacturing device of claim 1, further comprising:
a controller that independently controls an operation of the first chuck and the second chuck.

3. The manufacturing device of claim 2, wherein the controller includes a first controller that receives a dimension of the object and determines movement paths for the first chuck and the second chuck based on the dimension.

4. The manufacturing device of claim 2, wherein the controller includes a second controller that determines whether an alignment error of the display panel and the circuit board satisfies a first reference range.

5. The manufacturing device of claim 4, wherein the controller includes a third controller that determines whether a bending error, including a shape error and a position error of a bending portion of the object, satisfies a second reference range.

6. The manufacturing device of claim 5, wherein the second chuck moves in a direction of reducing the bending error in response to the bending error being outside of the second reference range.

7. The manufacturing device of claim 6, wherein
the bending portion is located between a first flat portion in the display panel and the second flat portion in the circuit board,
after the object is bent, the first flat portion and the second flat portion are stacked on each other, and the bending portion has a first radius, and
the second chuck moves in the direction of reducing the bending error, causing the bending portion to have a second radius different from the first radius.

8. The manufacturing device of claim 7, further comprising:
a camera located to photograph a side surface of the bending portion.

9. The manufacturing device of claim 5, wherein the controller includes a fourth controller that compares the alignment error and the bending error.

10. The manufacturing device of claim 1, wherein the second chuck includes a vacuum suction pad for vacuum suctioning a portion of the display panel.

11. A manufacturing method of a display device, comprising:
preparing an object including a circuit board connected to a display panel;
chucking a portion of the circuit board;
chucking a portion of the display panel; and
bending the object to form a first flat portion, a second flat portion stacked on the first flat portion, and a bending portion having a first radius between the first flat portion and the second flat portion.

12. The manufacturing method of claim 11, further comprising:
determining whether the bending error, including a shape error and a position error of the bending portion, satisfies a second reference range after bending the object.

13. The manufacturing method of claim 12, further comprising:
modifying a shape of the bending portion in response to the bending error being outside the second reference range.

14. The manufacturing method of claim 13, wherein the bending portion has a second radius that is different from the first radius after modifying the shape of the bending portion.

15. The manufacturing method of claim 13, further comprising:
determining whether the alignment error of the display panel and the circuit board satisfies a first reference range before bending the object and determining whether the bending error satisfies the second reference range.

16. The manufacturing method of claim 15, further comprising:
determining whether the bending error satisfies the second reference range in response to the alignment error satisfying the first reference range, wherein the bending error is determined based on an image photographed of a side surface of the bending portion.

17. The manufacturing method of claim 15, further comprising:
determining whether the shape and the position of the bending portion satisfy the second reference range before modifying the bending shape, and
comparing the alignment error and the bending error.

18. The manufacturing method of claim 17, wherein the bending shape is modified in response to the alignment error being smaller than or equal to the bending error.

19. The manufacturing method of claim 13, further comprising:
before chucking the object, inputting a dimension of the object; and
generating a first movement path for forming the bending portion and a second movement path for modifying the bending shape based on the dimension.

20. The manufacturing method of claim 11, further comprising vacuum suctioning the portion of the display panel in the chucking the portion of the display panel.
